(19) United States
(12) Patent Application Publication
(10) Pub. No.: US 2022/0221787 A1
(43) Pub. Date: Jul. 14, 2022

(54) METHODS AND APPARATUSES FOR DESIGNING SCRIBE LINE MARK AND LITHOGRAPHIC MASK LAYOUT

(71) Applicant: CHANGXIN MEMORY TECHNOLOGIES, INC, Hefei City (IL)

(72) Inventor: Yan ZHANG, Hefei City (CN)

(21) Appl. No.: 17/480,347

(22) Filed: Sep. 21, 2021

Related U.S. Application Data
(63) Continuation of application No. PCT/CN2021/100248, filed on Jun. 16, 2021.

(30) Foreign Application Priority Data
Jan. 8, 2021 (CN) 202110023164.6

(51) Int. Cl. G03F 1/42; G03F 7/20

(52) U.S. Cl. CPC G03F 1/42; G03F 7/705

(57) ABSTRACT

Disclosed are methods and apparatuses for designing a scribe line mark and a lithographic mask layout. The method for designing the scribe line mark includes: providing first scribe line marks, wherein the first scribe line marks include first portions which transmit light and second portions which transmit no light; and performing inverted processing on the first scribe line marks to form second scribe line marks, wherein the inverted processing includes: converting at least parts of the first portions which transmit light in the first scribe line marks into third portions which transmit no light, and converting at least parts of the second portions which transmit no light in the first scribe line marks into fourth portions which transmit light.

### CROSS-REFERENCE TO RELATED APPLICATIONS

This application is a continuation application of International Patent Application No. PCT/CN2021/100248, filed on Jun. 16, 2021, which claims priority to Chinese Patent Application No. 202110023164.6, filed with the Chinese Patent Office on Jan. 08, 2021 and entitled “METHODS AND APPARATUSES FOR DESIGNING SCRIBE LINE MARK AND LITHOGRAPHIC MASK LAYOUT.” International Patent Application No. PCT/CN2021/100248 and Chinese Patent Application No. 202110023164.6 are incorporated herein by reference in their entireties.

### TECHNICAL FIELD

The present disclosure relates to the field of semiconductors, and in particular, to methods and apparatuses for designing a scribe line mark and a lithographic mask layout.

### BACKGROUND

In a semiconductor manufacturing process, a lithographic process occupies the central position and is the most important process step in integrated circuit production. A semiconductor chip is generally fabricated to be multilayer, and patterns are required to be limited when each layer is fabricated, such that specific structures, such as contact holes or metal connecting lines, are formed. These patterns with the specific structures are generally limited by the lithographic process, while lithography is a technical process of transferring designed structural patterns to a wafer by virtue of lithographic masks.

Before a chip is manufactured, firstly, one or more lithographic masks are designed and fabricated according to the layout of devices, metal wires, connections and the like on each layer of the chip, and then, the patterns on the lithographic masks are transferred to the wafer by using the lithographic process. How to accurately reflect the designed patterns on the lithographic masks and then transfer the patterns to a semiconductor wafer is one of key problems concerned in semiconductor fabrication.

The lithographic mask is also referred to as a mask or photomask, is a flat panel having a light transmission property for exposure rays, and there is at least one geometric figure having a light shielding property for the exposure rays on the lithographic mask, such that light irradiated on a photoresist on the surface of the wafer may be selectively shielded, and finally, corresponding patterns are formed on the photoresist on the surface of the wafer.

The lithographic mask is also formed by using a certain fabrication process. Before the lithographic mask is fabricated, a lithographic mask layout is required to be designed, and various scribe line marks are required to be designed when the lithographic mask layout is designed. However, design processes of existing individual scribe line marks are relatively complicated.

### SUMMARY

How to increase the design efficiency of scribe line marks becomes a technical problem to be solved in the present disclosure.

The present disclosure provides a method for designing a scribe line mark, including:

providing first scribe line marks, wherein the first scribe line marks include first portions which transmit light and second portions which transmit no light; and

performing inverted processing on the first scribe line marks to form second scribe line marks, wherein the inverted processing includes: converting at least parts of the first portions which transmit light in the first scribe line marks into third portions which transmit no light, and converting at least parts of the second portions which transmit no light in the first scribe line marks into fourth portions which transmit light.

The present disclosure further provides a method for designing a lithographic mask layout, including:

providing a lithographic mask layout, wherein the lithographic mask layout includes several chip regions and scribe line regions located among the chip regions, several first scribe line marks are provided in the scribe line regions, and the first scribe line marks include first portions which transmit light and second portions which transmit no light; and

performing inverted processing on the several first scribe line marks to correspondingly form several second scribe line marks at positions where the several first scribe line marks are located, wherein the inverted processing includes: converting at least parts of the first portions which transmit light in the first scribe line marks into third portions which transmit no light, and converting at least parts of the second portions which transmit no light in the first scribe line marks into fourth portions which transmit light.

### BRIEF DESCRIPTION OF DRAWINGS

FIG. 1 to FIG. 7 are schematic structural diagrams in a process of designing scribe line marks according to an embodiment of the present disclosure;

FIG. 8 to FIG. 10 are schematic structural diagrams in a process of designing a lithographic mask layout according to another embodiment of the present disclosure; and

FIG. 11 is a schematic structural diagram of an apparatus for designing a scribe line mark according to an embodiment of the present disclosure.

### DESCRIPTION OF EMBODIMENTS

As stated in the background art, design processes of existing individual scribe line marks are relatively complicated.

According to a study, each scribe line mark is required to be designed alone when a lithographic mask layout is designed in the prior art. Many scribe line marks may be designed in scribe lines, and there are many kinds of scribe line marks, which leads to the relatively complicated and time-consuming design process.

To this end, the present disclosure provides methods and apparatuses for designing a scribe line mark and a lithographic mask layout, wherein the method for designing the scribe line mark includes that: first scribe line marks are provided, wherein the first scribe line marks include first portions which transmit light and second portions which transmit no light; and inverted processing is performed on the first scribe line marks to form second scribe line marks, wherein the inverted processing includes that: at least parts of the first portions which transmit light in the first scribe line marks are converted into third portions which transmit no light, and at least parts of the second portions which transmit no light in the first scribe line marks are converted into fourth portions which transmit light. In the present disclosure, when being designed, new scribe line marks may be achieved by only performing inverted processing on the existing first scribe line marks, and there is no need for complicated patterning design, size design and the like, such that the design process is greatly simplified, the design efficiency is increased, and the formed second scribe line marks may be directly applied to the design of a mask.

In order to provide a clear explanation and illustration, various embodiments herein are described in detail below with reference to the accompanying drawings. When describing the embodiments in detail, the schematic diagrams attached hereto, for illustrative purposes, are not partially enlarged based on the regular scale, and are not intended to limit the protection scope of the present disclosure, but only serve as examples. Besides, the three-dimensional size of length, width and depth should be made clear in practical application.

FIG. 1 to FIG. 7 are schematic structural diagrams in a process of designing scribe line marks according to an embodiment of the present disclosure.

Reference is made to FIG. 1 in which first scribe line marks 203 are provided, wherein the first scribe line marks 203 include first portions 201 which transmit light and second portions 202 which transmit no light.

The first scribe line marks 203 are marks required to be placed in scribe line regions of a lithographic mask layout in a design process of the lithographic mask layout. After the lithographic mask layout is designed, a lithographic mask may be fabricated according to the lithographic mask layout, then, a lithographic process is performed by using the fabricated lithographic mask, and the first scribe line marks on the lithographic mask are transferred to a scribe line of a wafer to form corresponding scribe line marks. It should be noted that the design process of the scribe line marks in the present embodiment and a design process of the lithographic mask layout in subsequent embodiments are both performed on EDA design software for integrated circuit fabrication, wherein the EDA design software includes Virtuoso software.

The first scribe line marks 203 are marks which have existed or designed. The first scribe line marks 203 may be marks having different or specific effects in integrated circuit fabrication. In a specific embodiment, the first scribe line marks 203 may be overlay marks for overlay measurement, alignment marks for alignment or measurement marks for electrical measurement. In other embodiments, the first scribe line marks may also be marks for other purposes in integrated circuit fabrication. In the present embodiment and the subsequent embodiments, an example in which the first scribe line marks 203 are used as the overlay marks for overlay measurement is described.

The first scribe line marks 203 include the first portions 201 which transmit light and the second portions 202 which transmit no light. The first portions 201 which transmit light means that light energy emitted by an exposure light source may be irradiated into a photoresist on a surface of a wafer after transmitting the first portions 201 of the first scribe line marks 203 on a lithographic mask after the first scribe line marks 203 are fabricated on the lithographic mask. The second portions 202 which transmit no light means that the light energy emitted by the exposure light source may not transmit the second portions 202 of the first scribe line marks 203 on the lithographic mask after the first scribe line marks 203 are fabricated on the lithographic mask, that is, light is shielded.

The specific shapes and/or sizes of the first portions 201 which transmit light and the second portions 202 which transmit no light of the first scribe line marks 203 are different according to the kinds and process demands of the scribe line marks designed as required differently. In the present embodiment, the first scribe line marks 203 include four first portions 201 which transmit light, the four first portions 201 which transmit light are not connected with each other and are arranged in a square, and the second portions 202 which transmit no light are arranged in the middle of and around the four first portions 201 which transmit light.

During specific design, in an embodiment, in order to facilitate subsequent pattern layer calculation, the first scribe line marks 203 are denoted by first pattern layers or are used as the first pattern layers. In the first pattern layers, the first portions 201 which transmit light and the second portions 202 which transmit no light are denoted by different filled patterns (for example, white elongated regions in FIG. 1 represent the first portions 201 which transmit light, and patterns filled with hatching represent the second portions 202 which transmit no light). Moreover, the first portions 201 which transmit light are marked to have a light transmission property, and the second portions 202 which transmit no light are marked to have a non-light transmission property. In a specific example, the light transmission property is denoted by “1” or “light transmission”, that is, for example, “1” or “light transmission” is used to mark that the first portions 201 have the light transmission property; and the non-light transmission property may be denoted by “0” or “non-light transmission”, that is, “0” or “non-light transmission” is used to mark that the second portions 202 have the non-light transmission property. In other embodiments, the light transmission property and the non-light transmission property may be denoted in other manners.

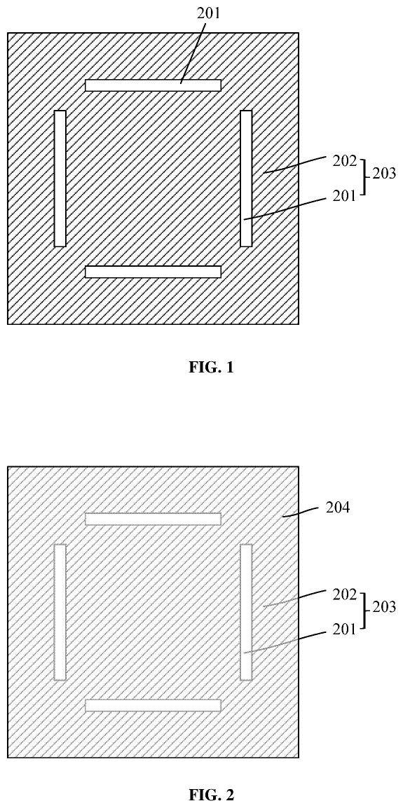

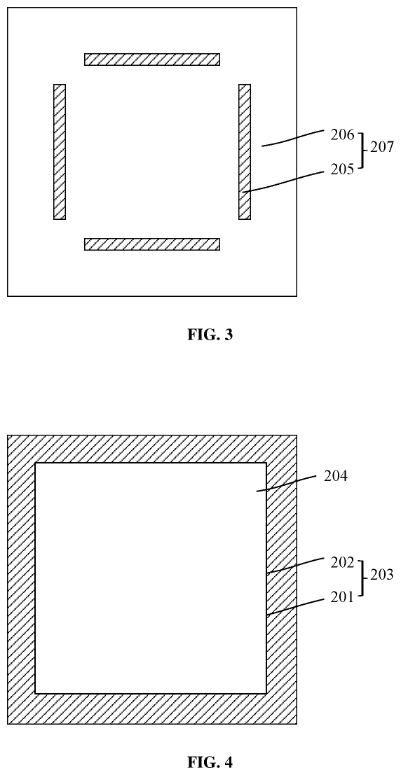

Reference is made to FIG. 2 and FIG. 3 in which inverted processing is performed on the first scribe line marks 203 to form second scribe line marks 207, wherein the inverted processing includes that: at least parts of the first portions 201 which transmit light in the first scribe line marks 203 are converted into third portions 205 which transmit no light, and at least parts of the second portions 202 which transmit no light in the first scribe line marks 203 are converted into fourth portions 206 which transmit light.

In the present disclosure, when being designed, new scribe line marks may be achieved by only performing inverted processing on the existing first scribe line marks 203, and there is no need for complicated patterning design, size design and the like, such that the design process is greatly simplified, the design efficiency is increased, and the formed second scribe line marks 207 may be directly applied to the design of a mask.

In the present embodiment, during inverted processing, inverted processing may be performed on all the first scribe line marks 203 to form the second scribe line marks 207, and thus, sizes of the second scribe line marks 207 which are the same as the first scribe line marks 203 in size and effect may be simply and conveniently formed (for example, all the first scribe line marks 203 are used for overlay measurement).

In an embodiment, a process of the inverted processing includes that: the first scribe line marks 203 are used as first pattern layers; the first pattern layers are covered with second pattern layers 204, wherein the second pattern layers 204 correspond to a size range where inverted processing is required in the first scribe line marks, and in the present embodiment, the second pattern layers 204 completely cover the first scribe line marks 203; and a pattern layer operation is performed on the first pattern layers and the second pattern layers in overlapping portions, the first portions which transmit light in the overlapping portions are converted into the third portions 205 which transmit no light, and the second portions which transmit no light in the overlapping portions are converted into the fourth portions 206 which transmit light, such that the second scribe line marks 207 are formed. The foregoing process enables the process of the inverted processing to be relatively simple and convenient.

All the second pattern layers 204 transmit light or not, and all the second pattern layers 204 are marked to have the non-light transmission property or the light transmission property (for example, “1” or “light transmission” is used to mark that all the second pattern layers have the light transmission property, and “0” or “non-light transmission” is used to mark that all the second pattern layers have the non-light transmission property) and are relevant with a pattern layer operation rule during pattern layer operation (when the first pattern layers are covered with the second pattern layers 204, the pattern layer operation is performed, and a corresponding pattern layer operation rule is called).

The pattern layer operation includes a Boolean operation. In an embodiment, the Boolean operation includes a True-False operation, that is, the True-False operation is performed on properties of the marks corresponding to the overlapping portions of the first pattern layers and the second pattern layers. For example, if both the overlapping portions have the light transmission property, for output, no light is transmitted; and if the overlapping portions have the non-light transmission property and the light transmission property, for output, light is transmitted. That is, correspondingly, the first portions which transmit light in the overlapping portions of the first pattern layers and the second pattern layers are converted into the third portions 205 which transmit no light, and the second portions which transmit no light in the overlapping portions of the first pattern layers and the second pattern layers are converted into the fourth portions 206 which transmit light. As shown in FIG. 2 and FIG. 3, the first portions 201 which transmit light in the first scribe line marks 203 in FIG. 2 are converted into the third portions 205 which transmit no light in FIG. 3, the second portions 202 which transmit no light in the first scribe line marks 203 in FIG. 2 are converted into the fourth portions 206 which transmit light in FIG. 3, and the third portions 205 which transmit no light and the fourth portions 206 which transmit light form the new second scribe line marks 207.

In another embodiment, the process of the inverted processing includes that: a size range requiring inverted processing in the first scribe line marks is selected; and a not operation is performed on the first scribe line marks within the selected size range, the first portions which transmit light in the selected first scribe line marks are converted into the third portions which transmit no light, and the second portions which transmit no light are converted into the fourth portions which transmit light. Particularly, the not operation is directly performed on the selected first scribe line marks. The foregoing process enables the process of the inverted processing to be relatively simple and convenient.

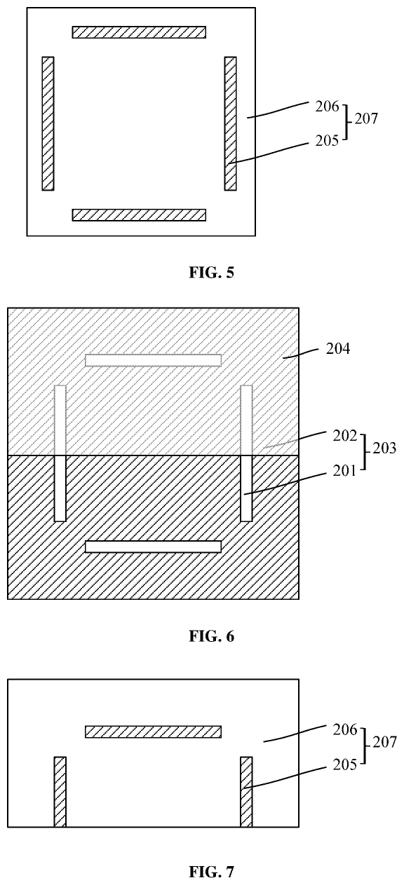

In other embodiments, inverted processing is performed on parts of the first scribe line marks to form the second scribe line marks. In an embodiment, reference is made to FIG. 4 and FIG. 5 in which the second pattern layers 204 only cover parts of the first scribe line marks 203, and thus, during inverted processing, inverted processing is only performed on the parts of first scribe line marks 203 which are covered by the second pattern layers (a specific process of the inverted processing refers to the foregoing description of corresponding portions, and will not be further explained herein), such that the second scribe line marks 207 are formed. In a specific embodiment, the second pattern layers 204 only cover the first scribe line marks 203 located on middle portions, while the first scribe line marks 203 located on edge portions are exposed, and inverted processing is performed on the first scribe line marks 203 located on the middle portions to form the second scribe line marks 207 as shown in FIG. 5. The second scribe line marks 207 in FIG. 5 differ from the first scribe line marks 203 in FIG. 4 in that sizes of the second scribe line marks 207 in FIG. 5 are less than those of the first scribe line marks 203 in FIG. 4, that is, the second scribe line marks 207 different from the first scribe line marks 203 in size may be formed by inverted processing, and the first scribe line marks 203 and the second scribe line marks 207 may have the same effects (for example, the both are used for overlay measurement).

In another embodiment, reference is made to FIG. 6 and FIG. 7 in which the second pattern layers 204 also only cover parts of the first scribe line marks 203.

Different from the previous embodiment, it lies in that positions, which are covered by the second pattern layers 204, of the first scribe line marks 203 are different. In the present embodiment, the second pattern layers 204 only cover the first scribe line marks 203 located on upper portions (reference is made to FIG. 6), and the first scribe line marks 203 on other portions are not covered; during inverted processing, inverted processing is only performed on the parts of first scribe line marks 203 covered by the second pattern layers (a specific process of the inverted processing refers to the foregoing description of corresponding portions, and will not be further explained herein), such that the second scribe line marks 207 are formed (reference is made to FIG. 7). That is, the second scribe line marks 207 different from the first scribe line marks 203 in size may be formed by inverted processing, and the first scribe line marks 203 and the second scribe line marks 207 may also have different effects (for example, the first scribe line marks 203 are used for overlay measurement, and the second scribe line marks 207 are used for alignment or electrical measurement). It should be noted that, in other embodiments, the second pattern layers 204 may only cover lower portions, left portions or right portions of the first scribe line marks 203 or cover the first scribe line marks 203 in other manners (for example, the upper and lower portions are covered, but the middle portions are exposed).

In an embodiment, before the inverted processing, a range of the first scribe line marks is extended. After extension, inverted processing is performed on the extended first scribe line marks to form the second scribe line marks, in this way, the second scribe line marks 207 of which the sizes become great as comparison with the first scribe line marks 203 may be formed, and the formed second scribe line marks 207 may have effects which are the same as or different from those of the first scribe line marks 203. The extension includes that the sizes of the first scribe line marks are extended.

Another embodiment of the present disclosure further provides a scribe line mark formed by using the foregoing method for designing the scribe line mark.

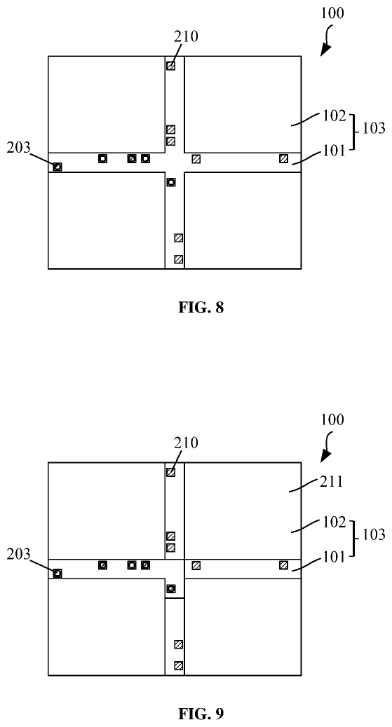

Further embodiment of the present disclosure further provides a method for designing a lithographic mask layout. Reference is made to FIG. 8 to FIG. 10.

Firstly, reference is made to FIG. 8 in which a lithographic mask layout 100 is provided, wherein the lithographic mask layout 100 includes several chip regions 102 and scribe line regions 101 located among the chip regions 102, several first scribe line marks 203 are provided in the scribe line regions 101, and the first scribe line marks 103 include first portions which transmit light and second portions which transmit no light.

The lithographic mask layout is used for fabricating a lithographic mask. The chip regions 102 of the lithographic mask layout 100 correspond to chip regions on a wafer, the scribe line regions 101 correspond to scribe line regions on the wafer, the chip regions are regions used for forming a chip or integrated circuit, and the scribe line regions are used for scribing chip after completing the fabrication of the integrated circuit. The provided lithographic mask layout 100 is an existing or initial lithographic mask layout, several first scribe line marks 203 are provided in the scribe line regions 101 of the lithographic mask layout 100, and the several first scribe line marks 203 are scribe line marks requiring inverted processing.

In an embodiment, the several first scribe line marks 203 are scribe line marks having different effects and/or different sizes.

In an embodiment, several third scribe line marks 210 are further provided in the scribe line regions 101, and the third scribe line marks 210 are scribe line marks which require no inverted processing.

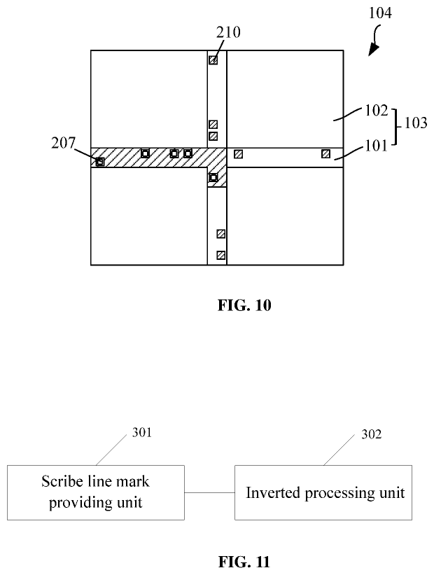

Reference is made to FIG. 9 and FIG. 10 in which inverted processing is performed on the several first scribe line marks 203 to correspondingly form several second scribe line marks 207 at positions where the several first scribe line marks 203 are located, wherein the inverted processing includes that: at least parts of the first portions which transmit light in the first scribe line marks are converted into third portions which transmit no light, and at least parts of the second portions which transmit no light in the first scribe line marks are converted into fourth portions which transmit light.

In the present disclosure, when the lithographic mask layout is designed, inverted processing is performed on the first scribe line marks 203 in a channel region on an existing lithographic mask layout to correspondingly form the new second scribe line marks 207 at the positions where the first scribe line marks 203 are located, and the second scribe line marks 207 are used as scribe line marks in a channel region of a new lithographic mask layout. Therefore, when a mask is designed, there is no need for complicated redesign (redesign of patterns and redesign of positions and layout) for the scribe line marks in the scribe line regions, such that the design process of the lithographic mask layout is greatly simplified, and the design efficiency is increased.

In an embodiment, inverted processing is performed on the several first scribe line marks 203 together to correspondingly form the several second scribe line marks at the positions where the several first scribe line marks are located, such that the design efficiency is further increased. Its specific process includes that: the chip regions 102 and the several third scribe line marks 210 are covered by shielding pattern layers 211, the several first scribe line marks 103 are exposed, and inverted processing is performed on the several exposed first scribe line marks 103 (a specific process of the inverted processing refers to the foregoing description of corresponding portions, and will not be further explained herein).

Yet further embodiment of the present disclosure further provides an apparatus for designing a scribe line mark. Reference is made to FIG. 11 in which the apparatus includes:

a scribe line mark providing unit 301, configured to provide first scribe line marks, wherein the first scribe line marks include first portions which transmit light and second portions which transmit no light; and

an inverted processing unit 302, configured to perform inverted processing on the first scribe line marks to form second scribe line marks, wherein the inverted processing includes that: at least parts of the first portions which transmit light in the first scribe line marks are converted into third portions which transmit no light, and at least parts of the second portions which transmit no light in the first scribe line marks are converted into fourth portions which transmit light.

In an embodiment, a process that the inverted processing unit 302 performs reverted processing includes that: the first scribe line marks are taken as first pattern layers; first pattern layers are covered with the second pattern layers, wherein the second pattern layers correspond to a size range where inverted processing is required in the first scribe line marks; and a pattern layer operation is performed on the first pattern layers and the second pattern layers in overlapping portions, the first portions which transmit light in the overlapping portions are converted into the third portions which transmit no light, and the second portions which transmit no light in the overlapping portions are converted into the fourth portions which transmit light.

In an embodiment, the pattern layer operation includes a Boolean operation, and the Boolean operation includes a True-False operation.

In another embodiment, a process that the inverted processing unit 302 performs inverted processing includes that: a size range requiring inverted processing in the first scribe line marks is selected; and a not operation is performed on the first scribe line marks within the selected size range, the first portions which transmit light in the selected first scribe line marks are converted into the third portions which transmit no light, and the second portions which transmit no light are converted into the fourth portions which transmit light.

In an embodiment, the inverted processing unit performs inverted processing on parts or all of the first scribe line marks to form the second scribe line marks.

Although the present disclosure has been disclosed as above in various embodiments, the present disclosure should not be limited by those embodiments. Those skilled in the art may make changes or modifications to the present disclosure based on the methods and technical solutions disclosed above without departing from the spirit and scope of the present disclosure. Therefore, any simple alterations, equivalent changes and modifications made to the foregoing embodiments based on the technical essence of the present disclosure without departing from the technical solutions proposed in the present disclosure are deemed to fall within the protection scope of the technical solutions in the present disclosure.

What is claimed is:

1. A method for designing a scribe line mark, comprising:
providing first scribe line marks, wherein the first scribe line marks comprise first portions which transmit light and second portions which transmit no light; and
performing inverted processing on the first scribe line marks to form second scribe line marks, wherein the inverted processing comprises: converting at least parts of the first portions which transmit light in the first scribe line marks into third portions which transmit no light, and converting at least parts of the second portions which transmit no light in the first scribe line marks into fourth portions which transmit light.

2. The method for designing the scribe line mark of claim 1, wherein a process of the inverted processing comprises: taking the first scribe line marks as first pattern layers; covering the first pattern layers with second pattern layers, wherein the second pattern layers correspond to a size range where inverted processing is required in the first scribe line marks; and performing a pattern layer operation on the first pattern layers and the second pattern layers in overlapping portions, converting the first portions which transmit light in the overlapping portions into the third portions which transmit no light, and converting the second portions which transmit no light in the overlapping portions into the fourth portions which transmit light.

3. The method for designing the scribe line mark of claim 2, wherein the pattern layer operation comprises a Boolean operation.

4. The method for designing the scribe line mark of claim 3, wherein the Boolean operation comprises a True-False operation.

5. The method for designing the scribe line mark of claim 1, wherein the process of the inverted processing comprises: selecting a size range requiring inverted processing in the first scribe line marks; and performing a not operation on the first scribe line marks within the selected size range, converting the first portions which transmit light in the selected first scribe line marks into the third portions which transmit no light, and converting the second portions which transmit no light into the fourth portions which transmit light.

6. The method for designing the scribe line mark of claim 1, wherein before the inverted processing, a range of the first scribe line marks is extended.

7. The method for designing the scribe line mark of claim 2, wherein inverted processing is performed on all the first scribe line marks to form the second scribe line marks.

8. The method for designing the scribe line mark of claim 2, wherein inverted processing is performed on parts of the first scribe line marks to form the second scribe line marks.

9. The method for designing the scribe line mark of claim 1, wherein the first scribe line marks and the second scribe line marks have the same or different effects.

10. A method for designing a lithographic mask layout, comprising:
providing a lithographic mask layout, wherein the lithographic mask layout comprises several chip regions and scribe line regions located among the chip regions, several first scribe line marks are provided in the scribe line regions, and the first scribe line marks comprise first portions which transmit light and second portions which transmit no light; and
performing inverted processing on the several first scribe line marks to correspondingly form several second scribe line marks at positions where the several first scribe line marks are located, wherein the inverted processing comprises: converting at least parts of the first portions which transmit light in the first scribe line marks into third portions which transmit no light, and converting at least parts of the second portions which transmit no light in the first scribe line marks into fourth portions which transmit light.

11. The method for designing the lithographic mask layout of claim 10, wherein inverted processing is performed on the several first scribe line marks together to correspondingly form the several second scribe line marks at the positions where the several first scribe line marks are located.

12. The method for designing the lithographic mask layout of claim 10, wherein the several first scribe line marks are scribe line marks having at least one of different effects or different sizes.

13. The method for designing the lithographic mask layout of claim 10, wherein several third scribe line marks are further provided in the scribe line regions, and the third scribe line marks are scribe line marks which require no inverted processing.

14. The method for designing the lithographic mask layout of claim 11, wherein the chip regions and the several third scribe line marks are covered by shielding pattern layers, the several first scribe line marks are exposed, and inverted processing is performed on the several exposed first scribe line marks.

15. An apparatus for designing a scribe line mark, comprising:
a scribe line mark providing unit, configured to provide first scribe line marks, wherein the first scribe line marks comprise first portions which transmit light and second portions which transmit no light; and
an inverted processing unit, configured to perform inverted processing on the first scribe line marks to form second scribe line marks, wherein the inverted processing comprises: converting at least parts of the first portions which transmit light in the first scribe line marks into third portions which transmit no light, and converting at least parts of the second portions which transmit no light in the first scribe line marks into fourth portions which transmit light.

16. The apparatus for designing the scribe line mark of claim 15, wherein a process that the inverted processing unit performs reverted processing comprises: taking the first scribe line marks as first pattern layers; covering first pattern layers with second pattern layers, wherein the second pattern layers correspond to a size range where inverted processing is required in the first scribe line marks; and performing a pattern layer operation on the first pattern layers and the second pattern layers in overlapping portions, converting the first portions which transmit light in the overlapping portions into the third portions which transmit no light, and converting the second portions which transmit no light in the overlapping portions into the fourth portions which transmit light.

17. The apparatus for designing the scribe line mark of claim 16, wherein the pattern layer operation comprises a Boolean operation, and the Boolean operation comprises a True-False operation.

18. The apparatus for designing the scribe line mark of claim 15, wherein a process that the inverted processing unit performs inverted processing comprises: selecting a size range requiring inverted processing in the first scribe line marks; and performing a not operation on the first scribe line marks within the selected size range, converting the first portions which transmit light in the selected first scribe line marks into the third portions which transmit no light, and converting the second portions which transmit no light into the fourth portions which transmit light.

19. The apparatus for designing the scribe line mark of claim 16, wherein the inverted processing unit performs inverted processing on parts or all of the first scribe line marks to form the second scribe line marks.
